(19) United States
(12) Patent Application Publication
(10) Pub. No.: US 2010/0187571 A1
(43) Pub. Date: Jul. 29, 2010

(54) SEMICONDUCTOR DEVICE AND MANUFACTURING METHOD THEREOF

(75) Inventors: Kenichi MIYAJIMA, Toyama (JP); Akiyoshi TAMURA, Osaka (JP); Keiichi MURAYAMA, Toyama (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/690,296

(22) Filed: Jan. 20, 2010

(30) Foreign Application Priority Data
Jan. 27, 2009 (JP) 2009-015955
Jan. 5, 2010 (JP) 2010-000810

(51) Int. Cl. H01L 29/08; H01L 21/8222

(52) U.S. Cl. 257/197; 438/318; 257/E29.033; 257/E21.608

(57) ABSTRACT

An object of the present invention is to provide a semiconductor resistive element having excellent linearity. A semiconductor device according to the present invention includes a HBT which is formed on a GaAs substrate and includes a group III-V compound semiconductor, and a semiconductor resistive element made of at least one layer included in a semiconductor epitaxial layer included in the HBT, and the semiconductor resistive element includes helium impurities.

### BACKGROUND OF THE INVENTION

(1) Field of the Invention

The present invention relates to a semiconductor resistive element, and particularly relates to a resistive element which includes a high-resistive semiconductor layer in a semiconductor circuit.

(2) Description of the Related Art

A semiconductor integrated circuit (semiconductor device) is configured by connecting an active element such as a heterojunction bipolar transistor (HBT) and a field-effect transistor (FET), and a passive element such as a resistive element, a capacitor, and an inductance by using metal wiring provided on a substrate. The resistive element, for example, is used for applying voltage to a transistor for biasing and requires a wide range of resistance. In other words, a higher resistance is necessary for applying a bias voltage at an input side of the transistor so as to control extra electric consumption, and a lower resistance is necessary for matching with output impedance at an output side of the transistor.

The semiconductor resistive element included in the semiconductor integrated circuit is formed by performing selective ion implantation and heat treatment for activation on the surface of the semiconductor substrate as in the case of forming the transistor. Alternatively, the semiconductor resistive element included in the semiconductor integrated circuit is formed by performing etching or high-resistance treatment on an unwanted part in an epitaxially-grown conductive semiconductor layer, a sputter-deposited metal film, and the like.

An example of such a semiconductor resistive element (for example, see: Japanese Unexamined Patent Application Publication No. 11-224931) is shown below.

The semiconductor resistive element is manufactured through a process shown in FIG. 10.

That is, as shown in FIG. 10(a), an n-type GaAs conductive semiconductor layer 202 is formed on a GaAs semiconductor substrate 201. Then, as shown in FIG. 10(b), boron ions (B⁺) are implanted into the n-type GaAs conductive semiconductor layer 202, and a semiconductor layer 203 having increased resistance is formed. Finally, the semiconductor layer 203 is heated for tens of minutes at a temperature of 450° C. to 600° C., so that the increased resistance is stabilized. Thus, the semiconductor resistive element which includes the semiconductor layer 203 as a resistive layer and an n-type GaAs conductive semiconductor layer 202 as a conductive layer is formed.

### SUMMARY OF THE INVENTION

Meanwhile, the semiconductor layer 203 which has increased resistance in the semiconductor resistive element described in the Patent Reference 1 is formed using B⁺ as ions to be implanted. Since B⁺ has a large mass number, an excessive defect is formed in the semiconductor layer. Thus, in the semiconductor resistive element in the Patent Reference 1, electrons are trapped in the defect, resulting in a failure to show satisfactory linearity. Note that the linearity is a volatility of resistance to a change in voltage and current.

In addition, in a semiconductor integrated circuit including the semiconductor resistive element formed on a substrate on which, for example, a vertical device such as the HBT using GaAs, is also provided, part of a base layer of the HBT is electrically isolated and further treated with ion implantation, to be formed into a resistive layer of the semiconductor resistive element. Then, below the resistive layer, a semiconductor layer electrically isolated from a collector layer of the HBT and a semiconductor layer electrically isolated from a subcollector layer of the HBT are provided. In the semiconductor integrated circuit, when B⁺ is selected as an ion species to be implanted to form the resistive layer, it is not possible to increase resistance of the semiconductor layer that is present below the resistive layer because B⁺ has a small range, and thus the semiconductor layer is present as a conductive layer. As a result, the semiconductor resistive element comes to include parasitic capacitance.

Thus, an object of the present invention, in view of the above problem, is to provide a semiconductor device which includes a semiconductor resistive element having excellent linearity.

To achieve the above object, a semiconductor device according to an aspect of the present invention is a semiconductor device including: an active element formed on a semiconductor substrate and including a group III-V compound semiconductor; and a semiconductor resistive element formed on the semiconductor substrate and including at least one layer included in a semiconductor epitaxial layer which is included in the active element, and the semiconductor resistive element includes helium impurities.

Since He⁺ has a smaller mass number than B⁺, it is possible to suppress generation of a defect in the resistive layer that is formed by implanting the He⁺ ions. Accordingly, compared to a resistive layer formed by implanting B⁺ ions, electrons are less likely to be trapped in the resistive layer formed by implanting the H⁺ ions, thus realizing the semiconductor resistive element which has satisfactory linearity.

In addition, since He⁺ has a wider range, it is also possible to implant He⁺ into a semiconductor layer that is present under the resistive layer by controlling the doze and accelerating voltage in the ion implantation condition for forming the resistive layer. In this case, it is also possible to increase resistance of the semiconductor layer that is present below the resistive layer, thus reducing the parasitic capacitance of the semiconductor resistive element.

Here, the active element may be the HBT. In addition, the active element may also be a BiFET.

According to this configuration, with the semiconductor resistive element that is formed on the same substrate on which the HBT or the BiFET is formed and that includes a resistive layer made of the group III-V compound semiconductor included in the base layer or the emitter contact layer, it is possible to achieve satisfactory linearity and reduced parasitic capacitance.

In addition, according to another aspect of the present invention, it is also possible to use a method for manufacturing a semiconductor device, which method includes: forming an active element made of a group III-V compound semiconductor, and forming a semiconductor resistive element including at least a semiconductor epitaxial layer which is included in the active element, the active element and the semiconductor resistive element being formed on a semiconductor substrate, and in the forming of a semiconductor resistive element, helium ions are implanted such that the semiconductor resistive element contains helium impurities.

According to this configuration, it is possible to manufacture a semiconductor resistive element having small parasitic capacitance and satisfactory linearity.

Here, an element isolating region for electrically isolating the active element, the semiconductor resistive element, and another element from each other may be formed at the same time by implanting the helium ions.

According to this configuration, since it is possible to form the resistive layer and the element isolating region at the same and thus reduce the number of processes, it is possible to manufacture the semiconductor resistive element in a simple manner.

According to the present invention, compared to a conventional resistive element with the resistive layer formed by implanting B⁺ ions, it is possible to manufacture a semiconductor device having a semiconductor resistive element which has excellent linearity.

### FURTHER INFORMATION ABOUT TECHNICAL BACKGROUND TO THIS APPLICATION

The disclosures of Japanese Patent Application No. 2009-015955 filed on Jan. 27, 2009 and No. 2010-000810 filed on Jan. 5, 2010 each including specification, drawings and claims are incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional view showing a structure of a semiconductor device according to a first embodiment of the present invention;

FIG. 2 is a diagram showing a current-voltage characteristic of a semiconductor resistive element according to the first embodiment;

FIG. 3 is a cross-sectional view showing a method for manufacturing the semiconductor device according to the first embodiment;

FIG. 4 is a cross-sectional view showing a structure of the semiconductor device according to a second embodiment of the present invention;

FIG. 5 is a cross-sectional view showing a method for manufacturing the semiconductor device according to the second embodiment;

FIG. 6 is a cross-sectional view showing a structure of a semiconductor device according to a third embodiment of the present invention;

FIG. 7 is a cross-sectional view showing a method for manufacturing the semiconductor device according to the third embodiment;

FIG. 8 is a cross-sectional view showing a structure of the semiconductor device according to a fourth embodiment of the present invention;

FIG. 9 is a cross-sectional view showing a method for manufacturing the semiconductor device according to the fourth embodiment; and

FIG. 10 is a cross-sectional diagram showing a structure of a conventional semiconductor resistive element.

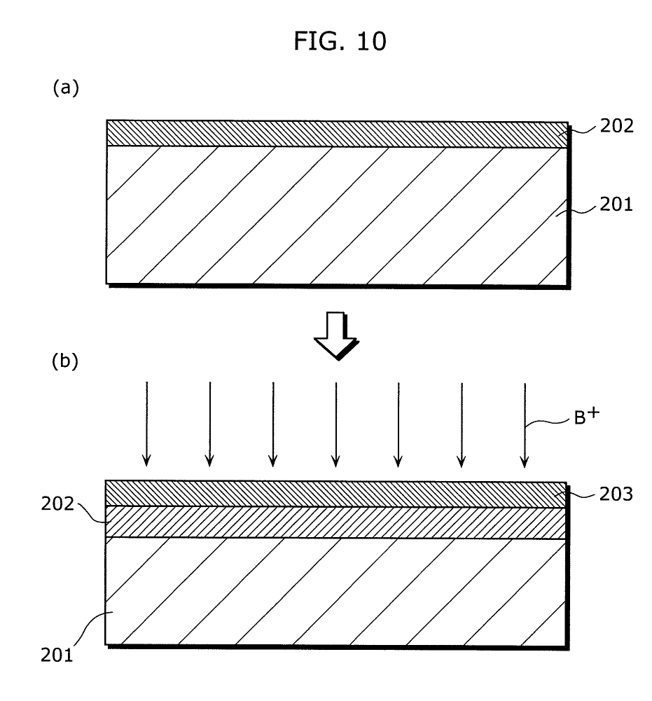

### DESCRIPTION OF THE PREFERRED EMBODIMENTS

Hereinafter, embodiments of the present invention will be described with reference to the drawings.

### First Embodiment

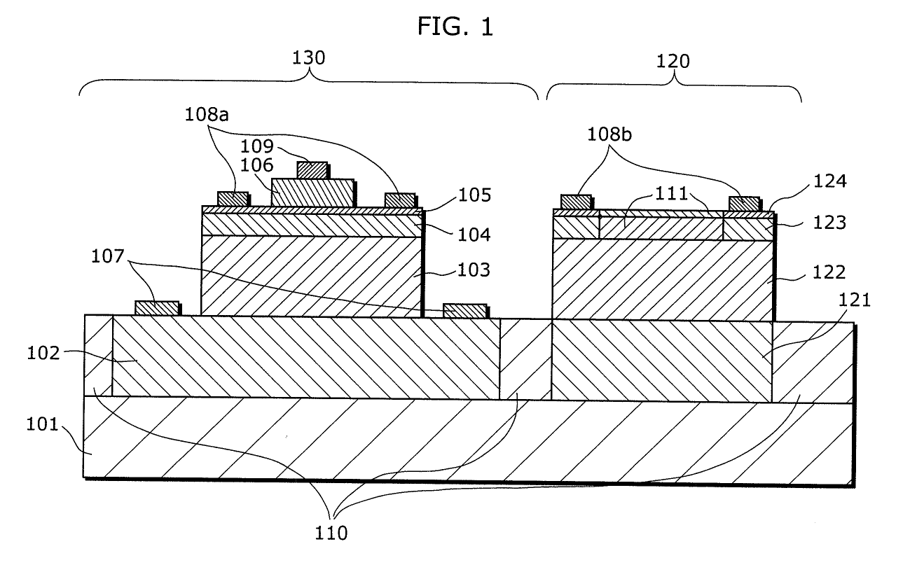

FIG. 1 is a cross-sectional view showing a structure of a semiconductor device according to a first embodiment of the present invention.

The semiconductor device includes a semiconductor resistive element 120 and a HBT 130 which are arranged side by side on a GaAs substrate 101 which is semi-insulating.

The HBT 130, as an example of an active element according to the present invention, is formed on the GaAs substrate 101 as a semiconductor substrate and includes a group III-V compound semiconductor. In addition, the semiconductor resistive element 120 is formed on the GaAs substrate 101 and includes at least one layer included in a semiconductor epitaxial layer which is included in the HBT 130, and includes helium impurities. Here, the semiconductor epitaxial layer includes a base layer of the HBT 130 as a layer included in the semiconductor resistive element 120, and the base layer in the HBT 130 has an impurity concentration at least two times higher than an impurity concentration of a subcollector layer in the HBT 130.

As shown in FIG. 1, the HBT 130 includes the following layers serially stacked on the GaAs substrate 101: a subcollector layer 102 made of n-type GaAs and doped with impurities at a high concentration of approximately 5×10¹⁸ cm⁻³; a collector layer 103 made of n-type GaAs doped with impurities at a low concentration of approximately 1×10¹⁶ cm⁻³; a base layer 104 made of p-type GaAs doped with impurities at a high concentration of approximately 4×10¹⁹ cm⁻³; an emitter layer 105 made of n-type InGaP doped with impurities of approximately 1×10¹⁷ cm⁻³ and having a bandgap wider than that of the base layer 104; and an emitter contact layer 106 having a laminated structure and made of n-type InGaAs doped with impurities at a high concentration of approximately 1×10¹⁹ cm⁻³.

The collector layer 103, the base layer 104, and the emitter layer 105, which are processed into a convex shape, constitute a base island region.

In addition, the emitter contact layer 106, which is processed into a convex shape, constitutes an emitter island region.

On a portion which is part of the subcollector layer 102 and exposed to the surface, a collector electrode 107 made of AuGe/Ni/Au and so on is formed. In addition, on a portion which is part of the emitter layer 105 and exposed to the surface, a base electrode 108a made of Pt/Ti/Pt/Au and so on is formed to have ohmic contact with the base layer 104, by thermal diffusion from the emitter layer 105. Furthermore, on the emitter contact layer 106, an emitter electrode 109 made of Pt/Ti/Pt/Au and so on is formed.

As shown in FIG. 1, the semiconductor resistive element 120 includes the following layers serially stacked on the GaAs substrate 101: a first semiconductor layer 121 made of n-type GaAs doped with impurities at a high concentration of approximately 5×10¹⁸ cm⁻³; a second semiconductor layer 122 made of n-type GaAs doped with impurities at a low concentration of 1×10¹⁶ cm⁻³; a third semiconductor layer 123 made of p-type GaAs doped with impurities at a high concentration of 4×10¹⁹ cm⁻³; and a fourth semiconductor layer 124 including n-type InGaP doped with impurities of approximately 1×10¹⁷ cm⁻³ and having a bandgap wider than that of the third semiconductor layer 123.

On a portion which is part of the fourth semiconductor layer 124 and exposed to the surface, two resistive element electrodes 108b made of Pt/Ti/Pt/Au and so on are formed to have ohmic contact with the third semiconductor layer 123, by thermal diffusion from the fourth semiconductor layer 124.

In a portion other than directly beneath the two resistive element electrodes 108b in the third semiconductor layer 123 and the fourth semiconductor layer 124, a resistive layer 111 having resistance increased by implanting helium ions (He⁺) is formed. That is, the resistive layer 111 which includes He⁺ as impurities is formed. At this time, the implanted He⁺ ions may reach the first semiconductor layer 121 and the second semiconductor layer 122.

The element isolating region 110 electrically isolates the semiconductor resistive element 120 and the HBT 130 from each other, and further, electrically isolates each of the semiconductor resistive element 120 and the HBT 130 from another element provided on the GaAs substrate 101.

Here, the first semiconductor layer 121 is formed by separating, by the element isolating region 110, the n-type GaAs layer included in the subcollector layer 102 into two electrically-isolated parts. Thus, the subcollector layer 102 and the first semiconductor layer 121 are formed in the same layer. Then, the element isolating region 110 is formed by implanting He⁺ ions into part of the n-type GaAs layer.

In addition, the second semiconductor layer 122 is formed by separating, by removal, the n-type GaAs layer included in the collector layer 103 into two electrically-isolated parts. Thus, the collector layer 103 and the second semiconductor layer 122 are formed in the same layer (formed in the same height, composition, and layer thickness).

In addition, the third semiconductor layer 123 is formed by separating, by removal, the p-type GaAs layer included in the base layer 104 into two electrically-isolated parts. Thus, the base layer 104 and the third semiconductor layer 123 are formed in the same layer.

In addition, the fourth semiconductor layer 124 is formed by separating, by removal, a semiconductor layer which includes the n-type InGaP layer included in the emitter layer 105, into two electrically-isolated parts. Thus, the emitter layer 105 and the fourth semiconductor layer 124 are formed in the same layer.

Note that the laminated body, which includes the n-type GaAs layer included in the subcollector layer 102, the n-type GaAs layer included in the collector layer 103, the p-type GaAs layer included in the base layer 104, the semiconductor layer including the n-type InGap layer that is included in the emitter layer 105, and the n-type InGaAs layer included in the emitter contact layer 106, is an example of a group III-V compound semiconductor layer according to the present invention.

The following will describe experimental results obtained for the semiconductor resistive element 120 in the semiconductor device having the above-described structure.

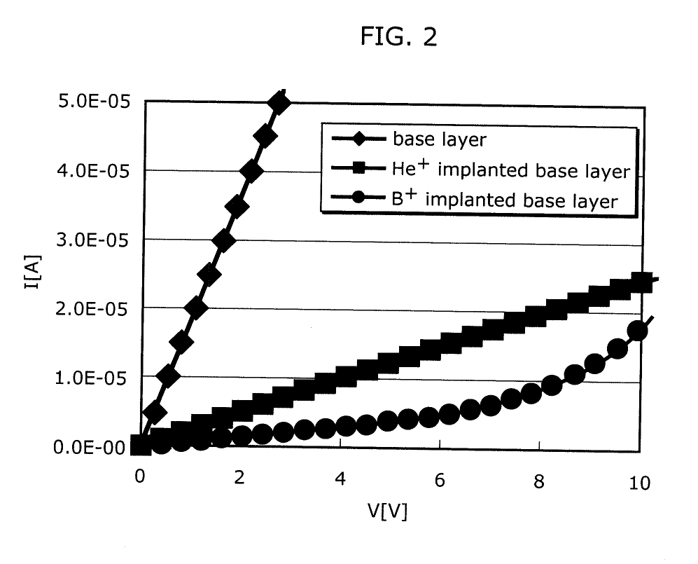

FIG. 2 is a diagram showing current-voltage characteristics of a resistive layer formed by implanting B⁺ ions into the p-type GaAs layer that is included in the base layer 104, and the resistive layer 111 formed by implanting He⁺ ions into the p-type GaAs layer that is included in the base layer 104.

As FIG. 2 shows, the conventional resistive layer formed by implanting B⁺ ions into the p-type GaAs layer included in the base layer and the resistive layer 111 according to the present embodiment which is formed by implanting He⁺ ions into the p-type GaAs layer included in the base layer 104 have higher gradient and higher resistance than those of the base layer 104 which is not ion-implanted. In addition, whereas the linearity of the conventional resistive layer starts collapsing at around 6 V and the resistance changes in response to voltage change, the resistive layer 111 according to the present embodiment maintains linearity without any change in resistance in response to the voltage change. This is because He⁺, which has a small mass number, can suppress generation of a defect in the semiconductor layer, so that electrons are less likely to be trapped when the semiconductor layer functions as the resistive layer.

Next, a method for manufacturing the semiconductor device having the above-described structure will be described.

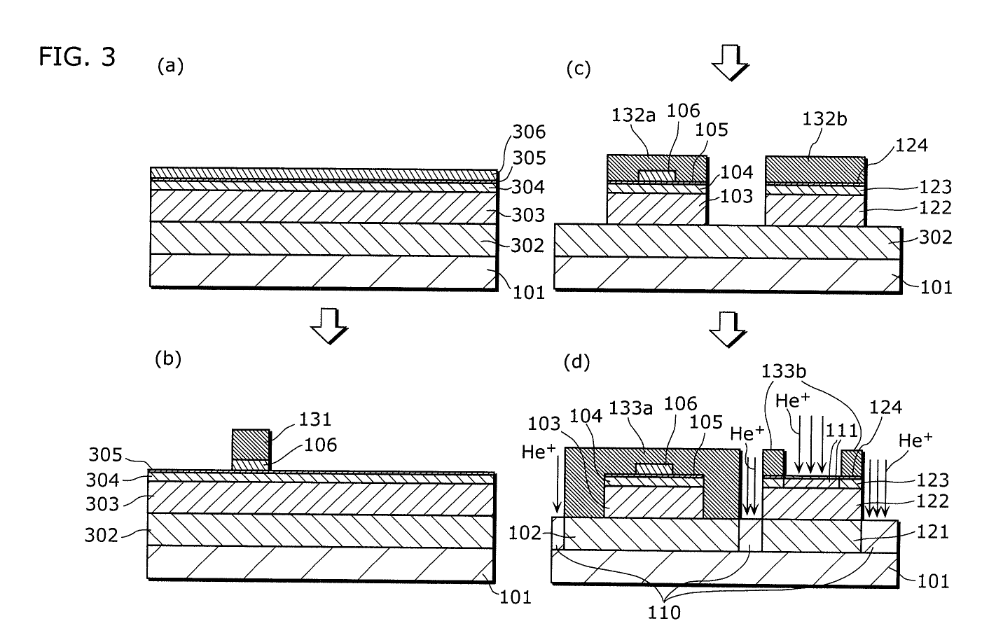

FIG. 3 is a cross-sectional view for describing the method for manufacturing the semiconductor device according to the first embodiment of the present invention.

The semiconductor device according to the first embodiment is formed by: forming the HBT 130 and the semiconductor resistive element 120 on the GaAs substrate 101, and implanting, when forming the semiconductor resistive element 120, helium ions such that the semiconductor resistive element 120 includes helium impurities. Then, the element isolating region for electrically isolating the HBT 130, the semiconductor resistive element 120, and another element from each other is formed by the implantation of the helium ions. In the implantation, the helium ions are implanted at a dose of 1×10¹² cm⁻² to 1×10¹⁴ cm⁻² inclusive.

Specifically, first, as shown in FIG. 3(a), by another crystal growth method such as a molecular beam epitaxial method (MBE method), a metalorganic chemical vapor deposition method (MOCVD method) or the like, stacked on the GaAs substrate 101 are: an n-type GaAs layer 302 doped with impurities at a high concentration of approximately 5×10¹⁸ cm⁻³; an n-type GaAs layer 303 doped with impurities at a low concentration of approximately 1×10¹⁶ cm⁻³; a p-type GaAs layer 304 doped with impurities at a high concentration of approximately 4×10¹⁹ cm⁻³; a semiconductor layer 305 including the n-type InGaP layer doped with impurities of approximately 1×10¹⁷ cm⁻³; and a laminated structure 306 including the n-type InGaAs layer doped with impurities at a high concentration of approximately 1×10¹⁹ cm⁻³. This laminated body, which is made up of the n-type GaAs layer 302, the n-type GaAs layer 303, the p-type GaAs layer 304, the semiconductor layer 305, and the laminated structure 306, is an example of the semiconductor epitaxial layer according to the present invention.

Next, as shown in FIG. 3(b), the emitter island region is protected by a photoresist mask 131, and a part of the laminated structure 306 is wet-etched or dry-etched. With this, the emitter island region, which is an emitter contact layer 106, is formed. At this time, the semiconductor layer 305 is hardly etched.

Next, as shown in FIG. 3(c), the base island region is protected by another photoresist mask 132a, and a region in which the semiconductor resistive element 120 is to be formed is protected by a photoresist mask 132b, and then the semiconductor layer 305, the p-type GaAs layer 304, and the n-type GaAs layer 303 are serially etched by wet etching or dry etching. With this, the base island region, that is, the collector layer 103, the base layer 104, and the emitter layer 105, and the second semiconductor layer 122, the third semiconductor layer 123, and the fourth semiconductor layer 124 that are in the semiconductor resistive element 120 are formed.

Next, as shown in FIG. 3(d), a photoresist mask 133a is formed to cover a region in which the HBT 130 is to be formed, and a photoresist mask 133b is further formed to cover a region in which a resistive element electrode 108b is to be formed. Subsequently, in a condition of accelerating voltage of 50 to 200 keV and a dose of 1×10¹² cm⁻² to 1×10¹⁴ cm⁻² inclusive, He⁺ ions are implanted into part of the fourth semiconductor layer 124 and the n-type GaAs layer 302 which are not covered with the photoresist masks 133a and 133b and are therefore exposed to the surface. By implanting He⁺ ions with this implantation condition, part of the n-type GaAs layer 302 with a doping concentration of around 5×10¹⁸ cm⁻³ becomes an element isolating layer in which almost no electric current flows. In addition, He⁺ ions implanted into the fourth semiconductor layer 124 are also implanted into the third semiconductor layer 123 through the fourth semiconductor layer 124. At this time, since the doping concentration of the third semiconductor layer 123 is approximately 4×10¹⁹ cm⁻³ and is at least two times higher than the doping concentration of the n-type GaAs layer 302, the ion-implanted portion of the fourth semiconductor layer 124 functions as a high-resistivity layer, unlike the element isolating layer in which almost no electric current flows. At this time, the implanted He⁺ may reach the first semiconductor layer 121 and the second semiconductor layer 122. With this, the subcollector layer 102, the resistive layer 111 and the element isolating region 110 are formed at the same time.

Next, the collector electrode 107, the base electrode 108a, the resistive element electrode 108b, and the emitter electrode 109 are serially formed. Note that these electrodes may be formed in any order.

Finally, thermal treatment is performed at a temperature of approximately 300° C. to 400° C. so as to simultaneously: provide an ohmic contact state to each of the collector electrode 107, the base electrode 108a, the resistive element electrode 108b, and the emitter electrode 109; inactivate the element isolating region 110; and activate the resistive layer 111.

As described above, according to the semiconductor device according to the first embodiment of the present invention, the resistive layer 111 in the semiconductor resistive element 120 is formed by implanting He⁺ ions into the conductive semiconductor layer. Since He⁺ has a smaller mass number than B⁺, it is possible to suppress occurrence of a defect in the resistive layer that is formed by implanting the He⁺ ions. Accordingly, compared to a resistive layer formed by implanting B⁺ ions, electrons are less likely to be trapped in the resistive layer 111, thus realizing the semiconductor resistive element 120 which has satisfactory linearity.

In addition, since He⁺ has a wider range, it is also possible to implant He⁺ into the second semiconductor layer 122 and the first semiconductor layer 121 by controlling the doze and accelerating voltage in the ion implantation condition for forming the resistive layer 111. In this case, it is also possible to increase resistance of the second semiconductor layer 122 and the first semiconductor layer 121 that are present below the resistive layer 111, thus allowing reduced parasitic capacitance of the semiconductor resistive element 120.

### Second Embodiment

Hereinafter, a semiconductor device according to a second embodiment of the present invention will be described in detail with reference to the drawings. Note that the semiconductor device according to present embodiment is different from the semiconductor device according to the first embodiment in that: in the semiconductor device according to the first embodiment, He⁺ ions are implanted into the third semiconductor layer 123 and the fourth semiconductor layer 124 to form the resistive layer 111, and the base layer 104 and the third semiconductor layer 123 are formed in the same layer, and the emitter layer 105 and the fourth semiconductor layer 124 are formed in the same layer; whereas, in the semiconductor device according to the present embodiment, as described later, He⁺ ions are implanted into a fifth semiconductor layer 125 to form a resistive layer 112, and an emitter contact layer 106 and the fifth semiconductor layer 125 are formed in the same layer.

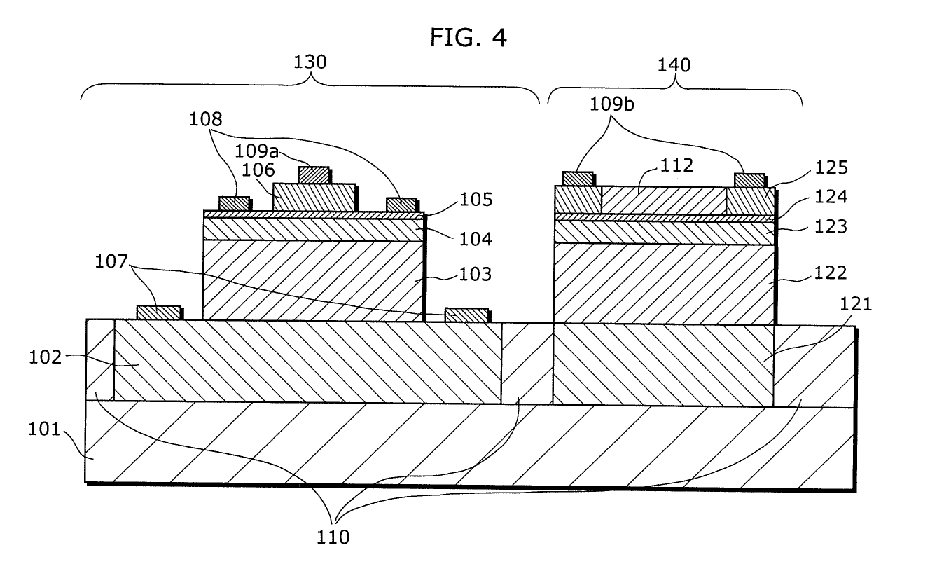

FIG. 4 is a cross-sectional view showing a structure of the semiconductor device according to the second embodiment of the present invention.

The semiconductor device includes a semiconductor resistive element 140 and a HBT 130 which are arranged side by side on the GaAs substrate 101 which is semi-insulating.

The HBT 130, as an example of an active element according to the present invention, is formed on the GaAs substrate 101 as a semiconductor substrate and includes a group III-V compound semiconductor. In addition, the semiconductor resistive element 140 is formed on the GaAs substrate 101 and includes at least one layer included in a semiconductor epitaxial layer which is included in the HBT 130, and includes helium impurities. Here, the semiconductor epitaxial layer includes an emitter contact layer of the HBT 130 as a layer included in the semiconductor resistive element 140, and the emitter contact layer of the HBT 130 has an impurity concentration at least two times higher than the impurity concentration of a subcollector layer of the HBT 130.

As shown in FIG. 4, the HBT 130 includes: a subcollector layer 102 made of n-type GaAs, which is serially stacked on the GaAs substrate 101 and doped with impurities at a high concentration of approximately 5×10¹⁸ cm⁻³; a collector layer 103 made of n-type GaAs doped with impurities at a low concentration of approximately 1×10¹⁶ cm⁻³; a base layer 104 made of p-type GaAs doped with impurities at a high concentration of approximately 4×10¹⁹ cm⁻³; an emitter layer 105 including n-type InGaP doped with impurities of approximately 1×10¹⁷ cm⁻³ and having a bandgap wider than that of the base layer 104; and an emitter contact layer 106 having a laminated structure and including n-type InGaAs doped with impurities at a high concentration of approximately 1×10¹⁹ cm⁻³.

The collector layer 103, the base layer 104, and the emitter layer 105, which are processed into a convex shape, constitute a base island region.

In addition, the emitter contact layer 106, which is processed into a convex shape, constitutes an emitter island region.

On a portion which is part of the sub-collector layer 102 and exposed to the surface, a collector electrode 107 made of AuGe/Ni/Au and so on is formed. In addition, on a portion which is part of the emitter layer 105 and exposed to the surface, a base electrode 108 made of Pt/Ti/Pt/Au and so on is formed to have ohmic contact with the base layer 104, by thermal diffusion from the emitter layer 105. Furthermore, on the emitter contact layer 106, an emitter electrode 109a made of Pt/Ti/Pt/Au and so on is formed.

As shown in FIG. 4, the semiconductor resistive element 140 includes the following layers serially stacked on the GaAs substrate 101: a first semiconductor layer 121 made of n-type GaAs doped with impurities at a high concentration of approximately 5×10¹⁸ cm⁻³; a second semiconductor layer 122 made of n-type GaAs doped with impurities at a low concentration of 1×10¹⁶ cm⁻³; a third semiconductor layer 123 made of p-type GaAs doped with impurities at a high concentration of 4×10¹⁹ cm⁻³; a fourth semiconductor layer 124 including n-type InGaP doped with impurities of approximately 1×10¹⁷ cm⁻³ and having a bandgap wider than that of the third semiconductor layer 123; and a fifth semiconductor layer 125 having a laminated structure and including n-type InGaAs doped with impurities of approximately 1×10¹⁹ cm⁻³.

On a portion which is part of the fifth semiconductor layer 125 and exposed to the surface, two resistive element electrodes 109b made of Pt/Ti/Pt/Au and so on are formed.

In a portion other than directly beneath the two resistive element electrodes 109b in the fifth semiconductor layer 125, a resistive layer 112 having resistance increased by implanting He⁺ ions is formed. That is, the resistive layer 112 which includes He⁺ as impurities is formed. At this time, the implanted He⁺ ions may reach the first semiconductor layer 121, the second semiconductor layer 122, the third semiconductor 123, and the fourth semiconductor 124.

The element isolating region 110 electrically isolates the semiconductor resistive element 140 and the HBT 130 from each other, and further, electrically isolates each of the semiconductor resistive element 140 and the HBT 130 from another element provided on the GaAs substrate 101.

Here, the first semiconductor layer 121 is formed by separating, by the element isolating region 110, the n-type GaAs layer included in the subcollector layer 102 into two electrically-isolated parts. Thus, the subcollector layer 102 and the first semiconductor layer 121 are formed in the same layer. Then, the element isolating region 110 is formed by implanting He⁺ ions into a part of the n-type GaAs layer.

In addition, the second semiconductor layer 122 is formed by separating, by removal, the n-type GaAs layer included in the collector layer 103 into two electrically-isolated parts. Thus, the collector layer 103 and the second semiconductor layer 122 are formed in the same layer (formed in the same height, composition, and layer thickness).

In addition, the third semiconductor layer 123 is formed by separating, by removal, the p-type GaAs layer included in the base layer 104 into two electrically-isolated parts. Thus, the base layer 104 and the third semiconductor layer 123 are formed in the same layer.

In addition, the fourth semiconductor layer 124 is formed by separating, by removal, a semiconductor layer including the n-type InGaP layer that is included in the emitter layer 105, into two electrically-isolated parts. Thus, the emitter layer 105 and the fourth semiconductor layer 124 are formed in the same layer.

In addition, the fifth semiconductor layer 125 are formed by separating, by removal, a semiconductor layer having a laminated structure and including the n-type InGaAs that is included in the emitter contact layer 106, into two electrically-isolated parts. Thus, the emitter contact layer 106 and the fifth semiconductor layer 125 are formed in the same layer.

Note that the laminated structure, which includes the n-type GaAs layer included in the sub-collector layer 102, the n-type GaAs layer included in the collector layer 103, the p-type GaAs layer included in the base layer 104, the semiconductor layer including the n-type InGap layer that is included in the emitter layer 105, and the n-type InGaAs layer included in the emitter contact layer 106, is an example of the group III-V compound semiconductor layer according to the present invention.

Next, a method for manufacturing the semiconductor device having the above-described structure will be described.

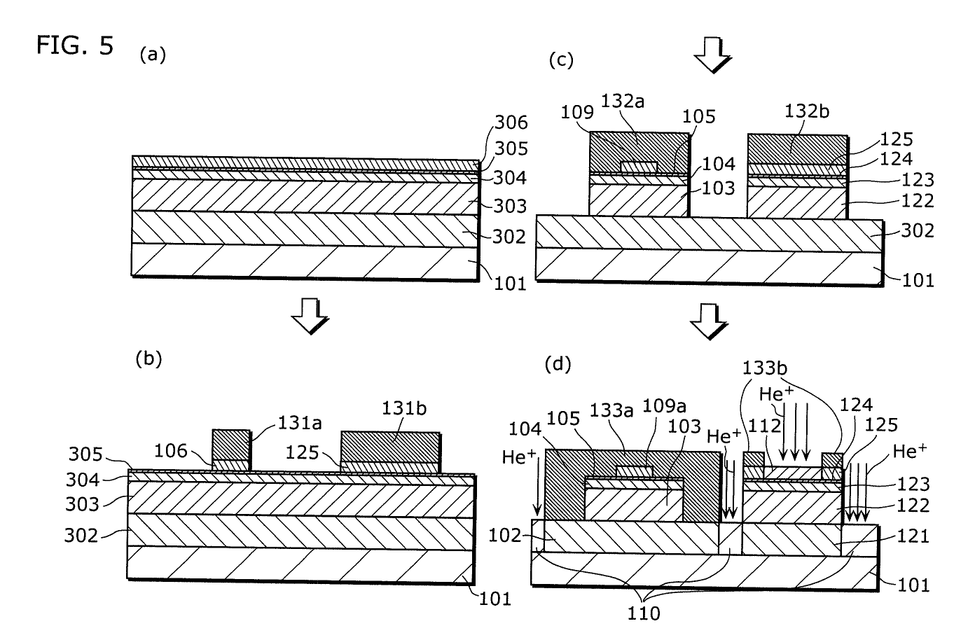

FIG. 5 is a cross-sectional view for describing the method for manufacturing the semiconductor device according to the second embodiment of the present invention.

The semiconductor device according to the second embodiment is formed by: forming the HBT 130 and the semiconductor resistive element 140 on the GaAs substrate 101, and implanting, when forming the semiconductor resistive element 140, helium ions such that the semiconductor resistive element 140 includes helium impurities. Then, an element isolating region for electrically isolating the HBT 130, the semiconductor resistive element 140, and another element from each other is formed by the implantation of the helium ions. In the implantation, the helium ions are implanted at a dose of 1×10¹² cm⁻² to 1×10¹⁴ cm⁻² inclusive.

Specifically, first, as shown in FIG. 5(a), by a crystal growth method such as a molecular beam epitaxial method (MBE method), a metalorganic chemical vapor deposition method (MOCVD method) or the like, stacked on the GaAs substrate 101 are: an n-type GaAs layer 302 doped with impurities at a high concentration of approximately 5×10¹⁸ cm⁻³; an n-type GaAs layer 303 doped with impurities at a low concentration of approximately 1×10¹⁶ cm⁻³; a p-type GaAs layer 304 doped with impurities at a high concentration of approximately 4×10¹⁹ cm⁻³; a semiconductor layer 305 including an n-type InGaP layer doped with impurities of approximately 1×10¹⁷ cm⁻³; and a laminated structure 306 including an n-type InGaAs layer doped with impurities at a high concentration of approximately 1×10¹⁹ cm⁻³. This laminated body, which is made up of the n-type GaAs layer 302, the n-type GaAs layer 303, the p-type GaAs layer 304, the semiconductor layer 305, and the laminated structure 306, is an example of the semiconductor epitaxial layer according to the present invention.

Next, as shown in FIG. 5(b), the emitter island region is protected by a photoresist mask 131a, and a region in which the semiconductor resistive element 140 is to be formed is protected by a photoresist mask 131b, and a part of the laminated structure is wet-etched or dry-etched. With this, the emitter island region, which is the emitter contact layer 106 and the fifth semiconductor layer 125 in the semiconductor resistive element 140, is formed. At this time, the semiconductor layer 305 is hardly etched.

Next, as shown in FIG. 5(c), the base island is protected by another photoresist mask 132a, and a region in which the semiconductor resistive element 140 is to be formed is protected by a photoresist mask 132b, and the semiconductor layer 305, the p-type GaAs layer 304, and the n-type GaAs layer 303 are serially etched by wet etching or dry etching. With this, the base island region is formed with: the collector layer 103, the base layer 104, the emitter layer 105, and the second semiconductor layer 122, the third semiconductor layer 123, and the fourth semiconductor layer 124 that are included in the semiconductor resistive element 140.

Next, as shown in FIG. 5(d), a photoresist mask 133a is formed to cover a region in which the HBT 130 is to be formed, and a photoresist mask 133b is further formed to cover a region in which the resistive element electrodes 109b are to be formed. Subsequently, in a condition of accelerating voltage of 50 to 200 keV and a dose of 1×10¹² cm⁻² to 1×10¹⁴ cm⁻² inclusive, He⁺ ions are implanted into part of the fifth semiconductor layer 125 and the n-type GaAs layer 302 which are not covered with the photoresist masks 133a and 133b and are therefore exposed to the surface. By implanting He⁺ ions with this implantation condition, part of the n-type GaAs layer 302 with a doping concentration of approximately 5×10¹⁸ cm⁻³ becomes an element isolating layer in which almost no electric current flows. At this time, since the doping concentration of the fifth semiconductor layer 125 is approximately 1×10¹⁹ cm⁻³ which is at least two times higher than the doping concentration of the n-type GaAs layer 302, the ion-implanted portion of the fifth semiconductor layer 125 functions as a high-resistivity layer, unlike the element isolating layer in which almost no electric current flows. In addition, the implanted He⁺ ions may reach the first semiconductor layer 121, the second semiconductor layer 122, the third semiconductor 123, and the fourth semiconductor 124. With this, the subcollector layer 102, the resistive layer 112, and the element isolating region 110 are formed at the same time.

Next, the collector electrode 107, the base electrode 108, the emitter electrode 109a, and the resistive element electrodes 109b are serially formed. Note that these electrodes may be formed in any order.

Finally, thermal treatment is performed at a temperature of approximately 300° C. to 400° C. so as to simultaneously: provide an ohmic contact state to each of the collector electrode 107, the base electrode 108, the emitter electrode 109a, and the resistive element electrodes 109b; inactivate the element isolating region 110; and activate the resistive layer 112.

As described above, according to the semiconductor device according to the second embodiment of the present invention, the resistive layer 112 in the semiconductor resistive element 140 is formed by implanting He⁺ ions into the conductive semiconductor layer. Since He⁺ has a smaller mass number than B⁺, it is possible to suppress generation of a defect in the resistive layer that is formed by implanting the He⁺ ions. Accordingly, compared to the resistive layer formed by implanting B⁺ ions, electrons are less likely to be trapped in the resistive layer 112, thus realizing the semiconductor resistive element 140 which has satisfactory linearity.

In addition, since He⁺ has a wider range, it is also possible to implant He⁺ into the fourth semiconductor layer 124, the third semiconductor layer 123, the second semiconductor layer 122, and the first semiconductor layer 121 by controlling the doze and accelerating voltage in the ion implantation condition for forming the resistive layer 112. In this case, it is also possible to increase resistance of the fourth semiconductor layer 124, the third semiconductor layer 123, the second semiconductor layer 122, and the first semiconductor layer 121 that are present below the resistive layer 112, thus achieving reduced parasitic capacitance of the semiconductor resistive element 140.

### Third Embodiment

Hereinafter, a semiconductor device according to a third embodiment of the present invention will be described in detail with reference to the drawings. Note that the semiconductor device according to present embodiment is different from the semiconductor device according to the first embodiment in that: in the semiconductor device according to the first embodiment, only the HBT is formed on the GaAs substrate as an active element; whereas, in the semiconductor device according to the present embodiment, as described later, a FET is also formed on the GaAs substrate as another active element in addition to the HBT.

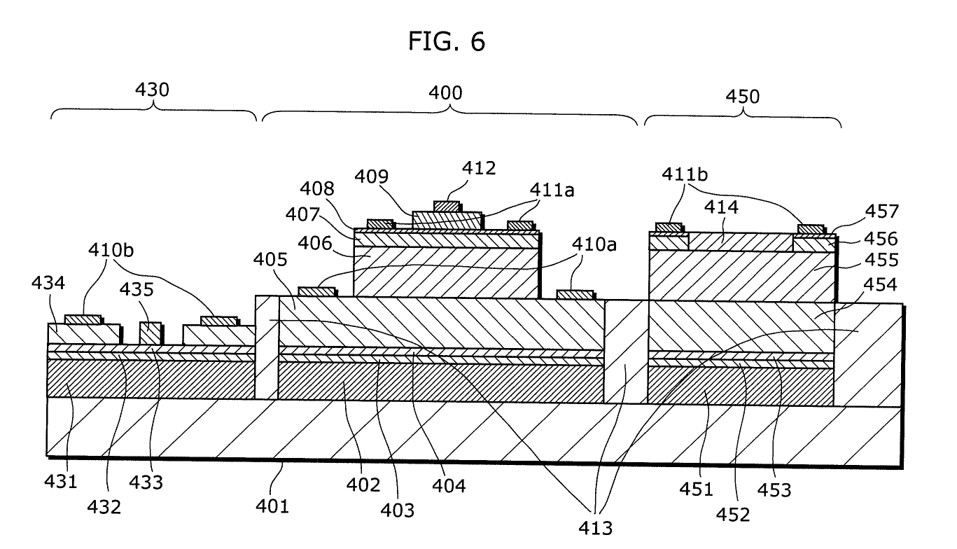

FIG. 6 is a cross-sectional view showing a structure of the semiconductor device according to the third embodiment of the present invention.

This semiconductor device includes a semiconductor resistive element 450, a HBT 400, and a FET 430 which are arranged side by side on a GaAs substrate 401 which is semi-insulating.

A BiFET, which is composed of the HBT 400 and FET 430 that are formed on the same semiconductor substrate (GaAs substrate 401), is an example of an active element according to the present invention and includes a group III-V compound semiconductor. In addition, the semiconductor resistive element 450 is formed on the GaAs substrate 401 and includes at least one layer included in a semiconductor epitaxial layer which is included in the BiFET, and includes helium impurities. Here, the semiconductor epitaxial layer includes a base layer of the BiFET as a layer included in the semiconductor resistive element 450, and the base layer in the BiFET has an impurity concentration at least two times higher than the impurity concentration of the subcollector layer in the BiFET.

As shown in FIG. 6, the HBT 400 includes the following layers serially stacked on the GaAs substrate 401: a buffer layer 402 having a laminated structure and including AlGaAS and GaAs; a channel layer 403 having a laminated structure and including InGaAs; a carrier supply layer 404 having a laminated structure and including AlGaAs; a subcollector layer 405 made of n-type GaAs doped with impurities at a high concentration of approximately 5×10¹⁸ cm⁻³; a collector layer 406 made of n-type GaAs doped with impurities at a low concentration of approximately 1×10¹⁶ cm⁻³; a base layer 407 made of p-type GaAs doped with impurities at a high concentration of approximately 4×10¹⁹ cm⁻³; an emitter layer 408 including n-type InGaP doped with impurities of approximately 1×10¹⁷ cm⁻³ and having a bandgap wider than that of the base layer 407; and an emitter contact layer 409 having a laminated structure and made of n-type InGaAs doped with impurities at a high concentration of approximately 1×10¹⁹ cm⁻³.

The collector layer 406, the base layer 407, and the emitter layer 408, which are processed into a convex shape, constitute a base island region.

In addition, the emitter contact layer 409, which is processed into a convex shape, constitutes an emitter island region.

On a portion which is part of the subcollector layer 405 and exposed to the surface, a collector electrode 410 made of AuGe/Ni/Au and so on is formed. In addition, on a portion which is part of the emitter layer 408 and exposed to the surface, a base electrode 411a made of Pt/Ti/Pt/Au and so on is formed to have ohmic contact with the base layer 407, by thermal diffusion from the emitter layer 408.

Furthermore, on the emitter contact layer 409, an emitter electrode 412 made of Pt/Ti/Pt/Au and so on is formed.

As shown in FIG. 6, the FET 430 includes the following layers serially stacked on the GaAs substrate 401: a buffer layer 431 having a laminated structure and including AlGaAs and GaAs which are serially stacked on the GaAs substrate 401; a channel layer 432 having a laminated structure and including InGaAs; a carrier supply layer 433 having a laminated structure and including AlGaAs; an ohmic contact layer 434 made of n-type GaAs doped with impurities at a high concentration of approximately 5×10¹⁸ cm⁻³.

On a portion which is part of the ohmic contact layer 434 and exposed to the surface, a source-drain electrode 410b made of AuGe/Ni/Au and so on is formed.

In addition, on a portion which is part of the carrier supply layer 433 and exposed to the surface, a gate electrode 435 made of Ti/Al/Ti and so on is formed.

As shown in FIG. 6, the semiconductor resistive element 450 includes the following layers serially stacked on the GaAs substrate 401: a first semiconductor layer 451 having a laminated structure and including AlGaAs and GaAs; a second semiconductor layer 452 having a laminated structure and including InGaAs; a third semiconductor layer 453 having a laminated structure and including AlGaAs; a fourth semiconductor layer 454 made of n-type GaAs doped with impurities at a high concentration of approximately 5×10¹⁸ cm⁻³; a fifth semiconductor layer 455 made of n-type GaAs doped with impurities at a low concentration of approximately 1×10¹⁶ cm⁻³; a sixth semiconductor layer 456 made of p-type GaAs doped with impurities at a high concentration of 4×10¹⁹ cm⁻³; and a seventh semiconductor layer 457 including n-type InGaP doped with impurities of approximately 1×10¹⁷ cm⁻³ and having a bandgap wider than that of the sixth semiconductor layer 456.

On a portion which is part of the seventh semiconductor layer 457 and exposed to the surface, two resistive element electrodes 411b made of Pt/Ti/Pt/Au and so on are formed to have ohmic contact with the sixth semiconductor layer 456, by thermal diffusion from the seventh semiconductor layer 457.

In a portion other than directly beneath the two resistive element electrodes 411b in the sixth semiconductor layer 456 and the seventh semiconductor layer 457, a resistive layer 414 having resistance increased by implanting helium ions (He⁺) is formed. That is, the resistive layer 414 which includes He⁺ as impurities is formed. At this time, the implanted He⁺ ions may reach the first semiconductor layer 451, the second semiconductor layer 452, the third semiconductor layer 453, the fourth semiconductor layer 454, and the fifth semiconductor layer 455.

The element isolating region 413 electrically isolates the semiconductor resistive element 450, the HBT 400, and the FET 430 from each other, and further, electrically isolates each of the semiconductor resistive element 450, the HBT 400, and the FET 430 from another element provided on the GaAs substrate 401.

Here, the first semiconductor layer 451 is formed by separating, by the element isolating region 413, a laminated semiconductor layer including the AlGaAs and GaAs that are included in the buffer layers 402 and 431, into electrically-isolated parts. Thus, the buffer layers 402 and 431, and the first semiconductor layer 451 are formed in the same layer.

The second semiconductor layer 452 is formed by separating, by the element isolating region 413, a laminated semiconductor layer including the InGaAs that is included in the channel layers 403 and 432, into electrically-isolated parts. Thus, the channel layers 403 and 432, and the second semiconductor layer 452 are formed in the same layer.

The third semiconductor layer 453 is formed by separating, by the element isolating region 413, a laminated semiconductor layer including the AlGaAs that is included in the carrier supply layers 404 and 433, into electrically-isolated parts. Thus, the carrier supply layers 404 and 433, and the third semiconductor layer 453 are formed in the same layer.

The ohmic contact layer 434 is formed by electrically isolating, by the element isolating region 413, an n-type GaAs layer included in the subcollector layer 405 and performing partial thinning by etching, and the fourth semiconductor layer 454 is formed by electrically isolating, by the element isolating region 413, the n-type GaAs layer included in the subcollector layer 405. Thus, the subcollector layer 405, the ohmic contact layer 434, and the fourth semiconductor layer 454 are formed in almost the same layer (formed in the same height and composition). Note that the ohmic contact layer 434 need not be thinned by the etching.

The fifth semiconductor layer 455 is formed by separating, by removal, an n-type GaAs layer included in the collector layer 406 into two electrically-isolated parts. Thus, the collector layer 406 and the fifth semiconductor layer 455 are formed in the same layer.

The sixth semiconductor layer 456 is formed by separating, by removal, a p-type GaAs layer included in the base layer 407 into two electrically-isolated parts. Thus, the base layer 407 and the sixth semiconductor layer 456 are formed in the same layer.

The seventh semiconductor layer 457 is formed by separating, by removal, a semiconductor layer including the n-type InGaP layer that is included in the emitter layer 408, into two electrically-isolated parts. Thus, the emitter layer 408 and the seventh semiconductor layer 457 are formed in the same layer.

Note that the laminated body, which includes the laminated semiconductor layer including the AlGaAs and GaAs that are included in the buffer layers 402 and 431, the laminated semiconductor layer including the InGaAs that is included in the channel layers 403 and 432, the n-type GaAs layer included in the subcollector layer 405 and the ohmic contact layer 434, the n-type GaAs layer included in the collector layer 406, the p-type GaAs layer included in the base layer 407, the semiconductor layer including the n-type InGaP layer that is included in the emitter layer 408, and the n-type InGaAs layer included in the emitter contact layer 409, is an example of the group III-V compound semiconductor layer according to the present invention.

Next, a method for manufacturing the semiconductor device having the above-described structure will be described.

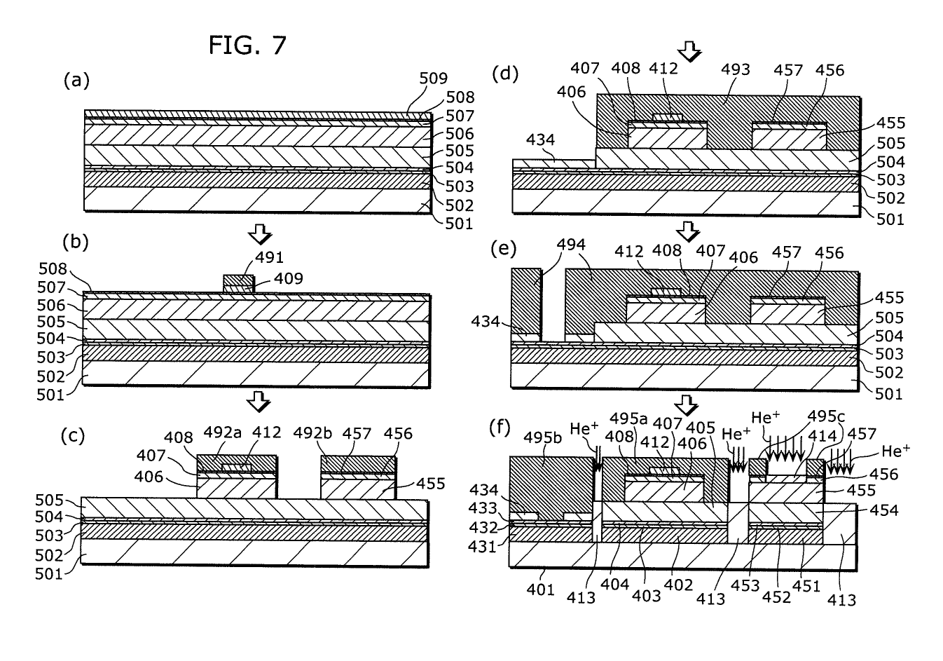

FIG. 7 is a cross-sectional view for describing the method for manufacturing the semiconductor device according to the third embodiment of the present invention.

The semiconductor device according to the third embodiment is formed by: forming the BiFET and the semiconductor resistive element 450 on the GaAs substrate 501, and implanting, when forming the semiconductor resistive element 450, helium ions such that the semiconductor resistive element 450 includes helium impurities. Then, an element isolating region for electrically isolating the BiFET, the semiconductor resistive element 450, and another element from each other is formed by the implantation of the helium ions. In the implantation, the helium ions are implanted at a dose of 1×10¹² cm⁻² to 1×10¹⁴ cm⁻² inclusive.

Specifically, first, as shown in FIG. 7(a), by a crystal growth method such as a molecular beam epitaxial method (MBE method), a metalorganic chemical vapor deposition method (MOCVD method) or the like, stacked on the GaAs substrate 501 are: a semiconductor layer 502 having a laminated structure and including AlGaAs and GaAs; a semiconductor layer 503 having a laminated structure and including InGaAs; a semiconductor layer 504 having a laminated structure and including AlGaAs; an n-type GaAs layer 505 doped with impurities at a high concentration of approximately 5×10¹⁸ cm⁻³; an n-type GaAs layer 506 doped with impurities at a low concentration of approximately 1×10¹⁶ cm⁻³; a p-type GaAs layer 507 doped with impurities at a high concentration of approximately 4×10¹⁹ cm⁻³; a semiconductor layer 508 including an n-type InGaP layer doped with impurities of approximately 1×10¹⁷ cm⁻³; and a laminated structure 509 including an n-type InGaAs layer doped with impurities at a high concentration of approximately 1×10¹⁹ cm⁻³. Such a laminated structure, which is made up of the semiconductor layers 502, 503, and 504, the n-type GaAs layers 505 and 506, the p-type GaAs layer 507, the semiconductor layer 508, and the laminated structure 509, is an example of the semiconductor epitaxial layer according to the present invention.

Next, as shown in FIG. 7(b), the emitter island region is protected by a photoresist mask 491, and a part of the laminated structure 509 is wet-etched or dry-etched. With this, the emitter island region, which is an emitter contact layer 409, is formed. At this time, the semiconductor layer 508 is hardly etched.

Next, as shown in FIG. 7(c), the base island region is protected by another photoresist mask 492a, and a region in which the semiconductor resistive element 405 is to be formed is protected by a photoresist mask 492b, and the semiconductor layer 508, the p-type GaAs layer 507, and the n-type GaAs layer 506 are serially etched by wet etching or dry etching. With this, the base island region is formed with: the collector layer 406, the base layer 407, the emitter layer 408, and the fifth semiconductor layer 455, the sixth semiconductor layer 456, and the seventh semiconductor layer 457 that are included in the semiconductor resistive element 450 are formed.

Next, as shown in FIG. 7(d), a portion other than a region in which the FET 430 is to be formed is protected by another photoresist mask 493, and the n-type GaAs layer 505 is thinned by wet etching or dry etching, and then the ohmic contact layer 434 is formed.

Next, as shown in FIG. 7(e), a portion other than a region in which the gate electrode 435 is to be formed is protected by another photoresist mask 494, and the ohmic contact layer 434 is etched by wet etching or dry etching, so that a concavity in which the gate electrode 435 is to be formed is provided.

Next, as shown in FIG. 7(f), a photoresist mask 495a is formed to cover a region in which the HBT 400 is to be formed, a photoresist mask 495b is formed to cover the region in which the FET 430 is to be formed, and further, a photoresist mask 495c is formed to cover a region in which the resistive element electrodes 411b are to be formed. Subsequently, in a condition of accelerating voltage 50 to 200 keV and a dose of 1×10¹² cm⁻² to 1×10¹⁴ cm⁻² inclusive, He⁺ ions are implanted into part of the seventh semiconductor layer 457 and the n-type GaAs layer 505 which are not covered with the photoresist masks 495a, 495b, and 495c and are therefore exposed to the surface. By implanting He⁺ ions with this implantation condition, the n-type GaAs layer 505 having a doping concentration of approximately 5×10¹⁸ cm⁻³ becomes an element isolating layer in which almost no electric current flows. In addition, the He⁺ ions implanted into the seventh semiconductor layer 457 are also implanted into the sixth semiconductor layer 456 via the seventh semiconductor layer 457. At this time, since the doping concentration of the sixth semiconductor layer 456 is approximately 4×10¹⁹ cm⁻³ and is at least two times higher than the doping concentration of the n-type GaAs layer 505, the ion-implanted portion of the sixth semiconductor layer 456 functions as a high-resistivity layer, unlike the element isolating layer in which almost no electric current flows. In addition, the implanted He⁺ ions may reach the first semiconductor layer 451, the second semiconductor layer 452, the third semiconductor 453, the fourth semiconductor 454, and the fifth semiconductor 455. With this, the subcollector layer 405, the ohmic contact layer 434, the resistive layer 414, and the element isolating region 413 are formed at the same time.

Next, the collector electrode 410a, the source-drain electrode 410b, the base electrode 411a, and the resistive element electrodes 411b, and the emitter electrode 412 are serially formed. Note that these electrodes may be formed in any order.

Finally, thermal treatment is performed at a temperature of approximately 300° C. to 400° C. so as to simultaneously: provide an ohmic contact state to each of the collector electrode 410a, the source-drain electrode 410b, the base electrode 411a, the resistive element electrodes 411b, and the emitter electrode 412; inactivate the element isolating region 413; and activate the resistive layer 414.

As described above, according to the semiconductor device according to the third embodiment of the present invention, the resistive layer 414 in the semiconductor resistive element 450 is formed by implanting He⁺ ions into the conductive semiconductor layer. Since He⁺ has a smaller mass number than B⁺, it is possible to suppress generation of a defect in the resistive layer that is formed by implanting the He⁺ ions. Accordingly, compared to the resistive layer formed by implanting B⁺ ions, electrons are less likely to be trapped in the resistive layer 414, thus realizing the semiconductor resistive element 450 which has satisfactory linearity.

In addition, since He⁺ has a wider range, it is also possible to implant He⁺ ions into the first semiconductor layer 451, the second semiconductor layer 452, the third semiconductor layer 453, the fourth semiconductor layer 454, and the fifth semiconductor layer 455 by controlling the doze and accelerating voltage in the ion implantation condition for forming the resistive layer 414. In this case, it is also possible to increase resistance of the first semiconductor layer 451, the second semiconductor layer 452, the third semiconductor layer 453, the fourth semiconductor layer 454, and the fifth semiconductor layer 455 that are present below the resistive layer 414, thus achieving reduced parasitic capacitance of the semiconductor resistive element 450.

### Fourth Embodiment

Hereinafter, a semiconductor device according to a fourth embodiment of the present invention will be described in detail with reference to the drawings. Note that the semiconductor device according to present embodiment is different from the semiconductor device according to the second embodiment in that: in the semiconductor device according to the second embodiment, only the HBT is formed on the GaAs substrate as an active element; whereas, in the semiconductor device according to the present embodiment, as described later, a FET is also formed on the GaAs substrate as another active element in addition to the HBT.

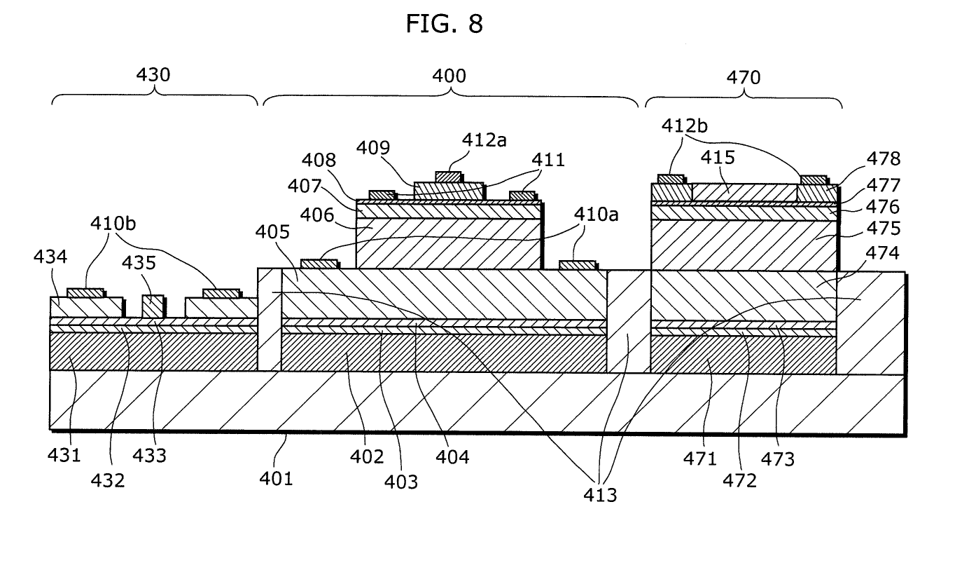

FIG. 8 is a cross-sectional view showing a structure of the semiconductor device according to the fourth embodiment of the present invention.

This semiconductor device includes a semiconductor resistive element 470, a HBT 400, and a FET 430 which are arranged side by side on the GaAs substrate 401 which is semi-insulating.

A BiFET, which is composed of the HBT 400 and FET 430 that are formed on the same semiconductor substrate (GaAs substrate 401), is an example of an active element according to the present invention and includes a group III-V compound semiconductor. In addition, the semiconductor resistive element 470 is formed on the GaAs substrate 401 and includes at least one layer included in a semiconductor epitaxial layer which is included in the BiFET, and includes helium impurities. Here, the semiconductor epitaxial layer includes an emitter contact layer of the BiFET as a layer included in the semiconductor resistive element 470, and the emitter contact layer of the BiFET has an impurity concentration at least two times higher than the impurity concentration of the subcollector layer of the BiFET.

As shown in FIG. 8, the HBT 400 includes the following layers serially stacked on the GaAs substrate 401: a buffer layer 402 having a laminated structure and including AlGaAs and GaAs; a channel layer 403 having a laminated structure and including InGaAs; a carrier supply layer 404 having a laminated structure and including AlGaAs; a subcollector layer 405 made of n-type GaAs doped with impurities at a high concentration of approximately 5×10¹⁸ cm⁻³; a collector layer 406 made of n-type GaAs doped with impurities at a low concentration of approximately 1×10¹⁶ cm⁻³; a base layer 407 made of p-type GaAs doped with impurities at a high concentration of approximately 4×10¹⁹ cm⁻³; an emitter layer 408 including n-type InGaP doped with impurities of approximately 1×10¹⁷ cm⁻³ and having a bandgap wider than that of the base layer 407; and an emitter contact layer 409 having a laminated structure and including n-type InGaAs doped with impurities at a high concentration of approximately 1×10¹⁹ cm⁻³.

The collector layer 406, the base layer 407, and the emitter layer 408, which are processed into a convex shape, constitute a base island region.

In addition, the emitter contact layer 409, which is processed into a convex shape, constitutes an emitter island region.

On a portion which is part of the subcollector layer 405 and exposed to the surface, a collector electrode 410a made of AuGe/Ni/Au and so on is formed. In addition, on a portion which is part of the emitter layer 408 and exposed to the surface, a base electrode 411 made of Pt/Ti/Pt/Au and so on is formed to have ohmic contact with the base layer 407, by thermal diffusion from the emitter layer 408. Furthermore, on the emitter contact layer 409, an emitter electrode 412a made of Pt/Ti/Pt/Au and so on is formed.

As shown in FIG. 8, the FET 430 includes the following layers serially stacked on the GaAs substrate 401: a buffer layer 431 having a laminated structure and including AlGaAs and GaAs; a channel layer 432 having a laminated structure and including InGaAs; a carrier supply layer 433 having a laminated structure and including AlGaAs; an ohmic contact layer 434 made of n-type GaAs doped with impurities at a high concentration of approximately 5×10¹⁸ cm⁻³.

On a portion which is part of the ohmic contact layer 434 and exposed to the surface, a source-drain electrode 410b made of AuGe/Ni/Au and so on is formed.

In addition, on a portion which is part of the carrier supply layer 433 and exposed to the surface, a gate electrode 435 made of Ti/Al/Ti and so on is formed.

As shown in FIG. 8, the semiconductor resistive element 470 includes the following layers serially stacked on the GaAs substrate 401: a first semiconductor layer 471 having a laminated structure and including AlGaAs and GaAs; a second semiconductor layer 472 having a laminated structure and including InGaAs; a third semiconductor layer 473 having a laminated structure and including AlGaAs; a fourth semiconductor layer 474 made of n-type GaAs doped with impurities at a high concentration of approximately 5×10¹⁸ cm⁻³; a fifth semiconductor layer 475 made of n-type GaAs doped with impurities at a low concentration of approximately 1×10¹⁶ cm⁻³; a sixth semiconductor layer 476 made of p-type GaAs doped with impurities at a high concentration of 4×10¹⁹ cm⁻³; a seventh semiconductor layer 477 including n-type InGaP doped with impurities of approximately 1×10¹⁷ cm⁻³ and having a bandgap wider than that of the sixth semiconductor layer 456; and an eighth semiconductor substrate 478 having a laminated structure and including n-type InGaAs doped with impurities of at a high concentration of approximately 1×10¹⁹ cm⁻³.

On a portion which is part of the eighth semiconductor layer 478 and exposed to the surface, two resistive element electrodes 412b made of Pt/Ti/Pt/Au and so on are formed.

In a portion other than directly beneath the two resistive element electrodes 412b in the eighth semiconductor layer 478, a resistive layer 415 having resistance increased by implanting helium ions (He⁺) is formed. That is, the resistive layer 415 which includes He⁺ as impurities is formed. At this time, the implanted He⁺ ions may reach the first semiconductor layer 471, the second semiconductor layer 472, the third semiconductor layer 473, the fourth semiconductor layer 474, the fifth semiconductor layer 475, the sixth semiconductor layer 476, and the seventh semiconductor layer 477.

The element isolating region 413 electrically isolates the semiconductor resistive element 470, the HBT 400, and the FET 430 from each other, and further, electrically isolates each of the semiconductor resistive element 470, the HBT 400, and the FET 430 from another element provided on the GaAs substrate 401.

Here, the first semiconductor layer 471 is formed by separating, by the element isolating region 413, a laminated semiconductor layer including the AlGaAs and GaAs that are included in the buffer layers 402 and 431, into electrically-isolated parts. Thus, the buffer layers 420 and 431, and the first semiconductor layer 471 are formed in the same layer.

The second semiconductor layer 472 is formed by separating, by the element isolating region 413, a laminated semiconductor layer including the InGaAs that is included in the channel layers 403 and 432, into electrically-isolated parts. Thus, the channel layers 403 and 432, and the second semiconductor layer 472 are formed in the same layer.

The third semiconductor layer 473 is formed by separating, by the element isolating region 413, a laminated semiconductor layer including the AlGaAs that is included in the carrier supply layers 404 and 433, into electrically-isolated parts. Thus, the carrier supply layers 404 and 433, and the third semiconductor layer 473 are formed in the same layer.

The ohmic contact layer 434 is formed by electrically isolating, by the element isolating region 413, an n-type GaAs layer included in the subcollector layer 405 and performing partial thinning by etching, and the fourth semiconductor layer 474 is formed by electrically isolating, by the element isolating region 413, the n-type GaAs layer included in the subcollector layer 405. Thus, the subcollector layer 405, the ohmic contact layer 434, and the fourth semiconductor layer 474 are formed in almost the same layer. Note that the ohmic contact layer 434 need not be thinned by the etching.

The fifth semiconductor layer 475 is formed by separating, by removal, an n-type GaAs layer included in the collector layer 406 into two electrically-isolated parts. Thus, the collector layer 406 and the fifth semiconductor layer 475 are formed in the same layer.

The sixth semiconductor layer 476 is formed by separating, by removal, a p-type GaAs layer included in the base layer 407, into two electrically-isolated parts. Thus, the base layer 407 and the sixth semiconductor layer 476 are formed in the same layer.

The seventh semiconductor layer 477 is formed by separating, by removal, a semiconductor layer including the n-type InGaP layer that is included in the emitter layer 408, into two electrically-isolated parts. Thus, the emitter layer 408 and the seventh semiconductor layer 477 are formed in the same layer.

In addition, the eighth semiconductor layer 478 is formed by separating, by removal, a semiconductor layer having a laminated structure and including the n-type InGaAs that is included in the emitter contact layer 409, into two electrically-isolated parts. Thus, the emitter contact layer 409 and the eighth semiconductor layer 478 are formed in the same layer.

Note that the laminated body, which includes the laminated semiconductor layer including the AlGaAs and GaAs that are included in the buffer layers 402 and 431, the laminated semiconductor layer including the InGaAs that is included in the channel layers 403 and 432, the n-type GaAs layer included in the subcollector layer 405 and the ohmic contact layer 434, the n-type GaAs layer included in the collector layer 406, the p-type GaAs layer included in the base layer 407, the semiconductor layer including the n-type InGaP layer that is included in the emitter layer 408, and the n-type InGaAs layer included in the emitter contact layer 409, is an examples of the group III-V compound semiconductor layer according to the present invention.

Next, a method for manufacturing the semiconductor device having the above-described structure will be described.

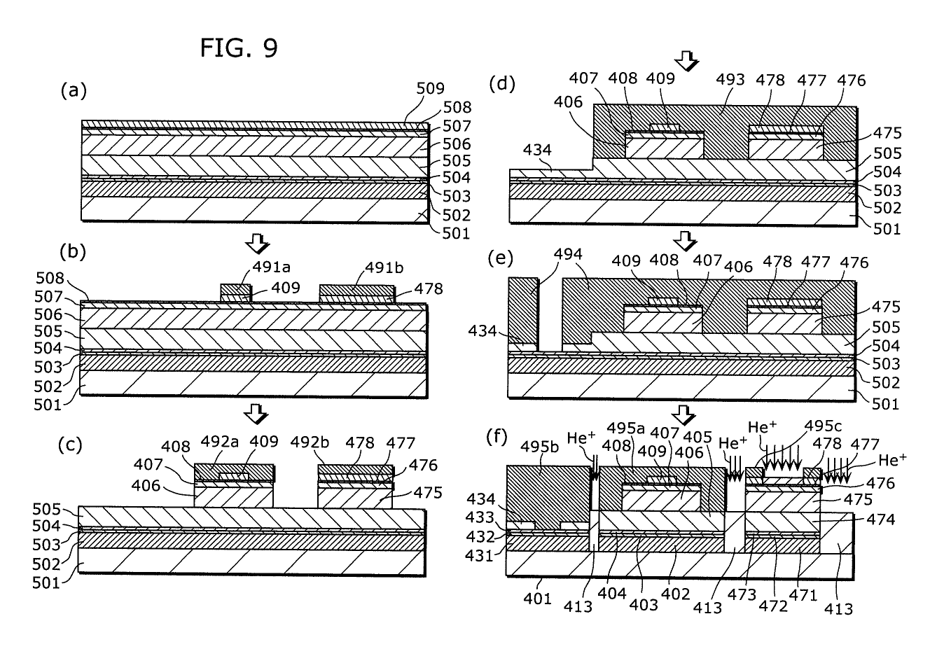

FIG. 9 is a cross-sectional view for describing the method for manufacturing the semiconductor device according to the fourth embodiment of the present invention.

The semiconductor device according to the fourth embodiment is formed by: forming the BiFET and the semiconductor resistive element 470 on the GaAs substrate 501, and implanting, when forming the semiconductor resistive element 470, helium ions such that the semiconductor resistive element 470 includes helium impurities. Then, an element isolating region for electrically isolating the BiFET, the semiconductor resistive element 470, and another element from each other is formed by the implantation of the helium ions. In the implantation, the helium ions are implanted at a dose of 1×10¹² cm⁻² to 1×10¹⁴ cm⁻² inclusive.

Specifically, first, as shown in FIG. 9(a), by a crystal growth method such as a molecular beam epitaxial method (MBE method), a metalorganic chemical vapor deposition method (MOCVD method) or the like, stacked on the GaAs substrate 501 are: a semiconductor layer 502 having a laminated structure and including AlGaAs and GaAs; a semiconductor layer 503 having a laminated structure and including InGaAs; a semiconductor layer 504 having a laminated structure and including AlGaAs; an n-type GaAs layer 505 doped with impurities at a high concentration of approximately 5×10¹⁸ cm⁻³; an n-type GaAs layer 506 doped with impurities at a low concentration of approximately 1×10¹⁶ cm⁻³; a p-type GaAs layer 507 doped with impurities at a high concentration of approximately 4×10¹⁹ cm⁻³; a semiconductor layer 508 including an n-type InGaP layer doped with impurities of approximately 1×10¹⁷ cm⁻³; and a laminated structure 509 including an n-type InGaAs layer doped with impurities at a high concentration of approximately 1×10¹⁹ cm⁻³. The laminated body, which is made up of the semiconductor layers 502, 503, and 504, the n-type GaAs layers 505 and 506, the p-type GaAs layer 507, the semiconductor layer 508, and the laminated structure 509, is an example of the semiconductor epitaxial layer according to the present invention.

Next, as shown in FIG. 9(b), the emitter island region is protected by a photoresist mask 491a, and a region in which the semiconductor resistive element 470 is to be formed is protected by a photoresist mask 491b, and a part of the laminated structure 509 is wet-etched or dry-etched. With this, the emitter island region, which is an emitter contact layer 409 and the eighth semiconductor layer 478 in the semiconductor resistive element 470, is formed. At this time, the semiconductor layer 508 is hardly etched.

Next, as shown in FIG. 9(c), the base island region is protected by another photoresist mask 492a, and a region in which the semiconductor resistive element 470 is to be formed is protected by a photoresist mask 492b, and the semiconductor layer 508, the p-type GaAs layer 507, and the n-type GaAs layer 506 are serially etched by wet etching or dry etching. With this, the base island region, that is, the collector layer 406, the base layer 407, and the emitter layer 408, and the fifth semiconductor layer 475, the sixth semiconductor layer 476, and the seventh semiconductor layer 477 that are included in the semiconductor resistive element 470 are formed.

Next, as shown in FIG. 9(d), a portion other than a region in which the FET 430 is to be formed is protected by another photoresist mask 493, and the n-type GaAs layer 505 is thinned by wet etching or dry etching, and then the ohmic contact layer 434 is formed.

Next, as shown in FIG. 9(e), a portion other than a region in which the gate electrode 435 is to be formed is protected by another photoresist mask 494, and the ohmic contact layer 434 is etched by wet etching or dry etching, so that a concavity in which the gate electrode 435 is to be formed is provided.

Next, as shown in FIG. 9(f), a photoresist mask 495a is formed to cover a region in which the HBT 400 is to be formed, a photoresist mask 495b is formed to cover the region in which the FET 430 is to be formed, and further, a photoresist mask 495c is formed to cover a region in which the resistive element electrodes 412b are to be formed. Subsequently, in a condition of accelerating voltage 50 to 200 keV and a dose of 1×10¹² cm⁻² to 1×10¹⁴ cm⁻² inclusive, He⁺ ions are implanted into part of the eighth semiconductor layer 478 and the n-type GaAs layer 505 which are not covered with the photoresist masks 495a, 495b, and 495c and are therefore exposed to the surface. By implanting the He⁺ ions with this implantation condition, the n-type GaAs layer 505 having a doping concentration of approximately 5×10¹⁸ cm⁻³ becomes an element isolating layer in which almost no electric current flows. At this time, since the doping concentration of the eighth semiconductor layer 478 is approximately 1×10¹⁹ cm⁻³ and is at least two times higher than the doping concentration of the n-type GaAs layer 505, the ion-implanted portion of the eighth semiconductor layer 478 functions as a high-resistivity layer, unlike the element isolating layer in which almost no electric current flows. In addition, the implanted He⁺ ions may reach the first semiconductor layer 471, the second semiconductor layer 472, the third semiconductor layer 473, the fourth semiconductor layer 474, the fifth semiconductor layer 475, the sixth semiconductor layer 476, and the seventh semiconductor layer 477. With this, the subcollector layer 405, the ohmic contact layer 434, the resistive layer 415, and the element isolating region 413 are formed at the same time.

Next, the collector electrode 410a, the source-drain electrode 410b, the base electrode 411, the emitter electrode 412a, and the resistive element electrodes 412b are serially formed. Note that these electrodes may be formed in any order.

Finally, thermal treatment is performed at a temperature of approximately 300° C. to 400° C. so as to simultaneously provide: an ohmic contact state to each of the collector electrode 410a, the source-drain electrode 410b, the base electrode 411, the emitter electrode 412a, and the resistive element electrodes 412b; inactivate the element isolating region 413; and activate the resistive layer 415.

As described above, according to the semiconductor device according to the fourth embodiment of the present invention, the resistive layer 415 in the semiconductor resistive element 470 is formed by implanting He⁺ ions into the conductive semiconductor layer. Since He⁺ has a smaller mass number than B⁺, it is possible to suppress occurrence of a defect in the resistive layer that is formed by implanting the He⁺ ions. Accordingly, compared to the resistive layer formed by implanting B⁺ ions, electrons are less likely to be trapped in the resistive layer 415, thus realizing the semiconductor resistive element 470 which has satisfactory linearity.

In addition, since He⁺ has a wider range, it is also possible to implant He⁺ into the first semiconductor layer 471, the second semiconductor layer 472, the third semiconductor layer 473, and the fourth semiconductor layer 474, the fifth semiconductor layer 475, the sixth semiconductor layer 476, and the seventh semiconductor layer 477 by controlling the doze and accelerating voltage in the ion implantation condition for forming the resistive layer 415. In this case, it is also possible to increase resistance of the first semiconductor layer 471, the second semiconductor layer 472, the third semiconductor layer 473, the fourth semiconductor layer 474, the fifth semiconductor layer 475, the sixth semiconductor 476, and the seventh semiconductor 477 that are present below the resistive layer 415, thus achieving reduced parasitic capacitance of the semiconductor resistive element 470.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

In addition, in the semiconductor integrated circuit described in the above embodiments, the resistive layer is formed by implanting He⁺ ions into the semiconductor layer including the p-type GaAs layer that is included in the base layer and the n-type InGaP layer that is included in the emitter layer. However, the semiconductor layer which becomes the resistive layer by implanting the H⁺ ions is not limited to these embodiments as long as the semiconductor layer is made of a conductive group III-V compound semiconductor, and it goes without saying that the same effects can be produced as in the semiconductor integrated circuit according to the above embodiments.

### INDUSTRIAL APPLICABILITY

The present invention is applicable to a semiconductor resistive element, and is particularly applicable to a device integrated with a transistor using GaAs.

What is claimed is:

1. A semiconductor device comprising:
an active element formed on a semiconductor substrate and including a group III-V compound semiconductor; and
a semiconductor resistive element formed on the semiconductor substrate and including at least one layer included in a semiconductor epitaxial layer which is included in said active element,
wherein said semiconductor resistive element includes helium impurities.

2. The semiconductor device according to claim 1,
wherein said active element is a heterojunction bipolar transistor.

3. The semiconductor device according to claim 2,
wherein the semiconductor epitaxial layer includes a base layer of the heterojunction bipolar transistor as a layer included in said semiconductor resistive element.

4. The semiconductor device according to claim 3,
wherein the base layer has an impurity concentration at least two times higher than an impurity concentration of a subcollector layer of the heterojunction bipolar transistor.

5. The semiconductor device according to claim 2,
wherein the semiconductor epitaxial layer includes an emitter contact layer of the heterojunction bipolar transistor as a layer included in said semiconductor resistive element.

6. The semiconductor device according to claim 5,
wherein the emitter contact layer has an impurity concentration at least two times higher than an impurity concentration of a subcollector layer of the heterojunction bipolar transistor.

7. The semiconductor device according to claim 1,
wherein said active element is a BiFET composed of the heterojunction bipolar transistor and a field-effect transistor which are formed on a same substrate.

8. The semiconductor device according to claim 7,
wherein the semiconductor epitaxial layer includes a base layer of the BiFET as a layer included in said semiconductor resistive element.

9. The semiconductor device according to claim 8,
wherein the base layer has an impurity concentration at least two times higher than an impurity concentration of a subcollector layer of the BiFET.

10. The semiconductor device according to claim 7,
wherein the semiconductor epitaxial layer includes an emitter contact layer of the BiFET as a layer included in said semiconductor resistive element.

11. The semiconductor device according to claim 10,
wherein the emitter contact layer has an impurity concentration at least two times higher than an impurity concentration of a subcollector layer of the BiFET.

12. A method for manufacturing a semiconductor device, said method comprising:
forming an active element made of a group III-V compound semiconductor, and forming a semiconductor resistive element including at least a semiconductor epitaxial layer which is included in the active element, the active element and the semiconductor resistive element being formed on a semiconductor substrate,
wherein in said forming of a semiconductor resistive element, helium ions are implanted such that the semiconductor resistive element contains helium impurities.

13. The method for manufacturing a semiconductor device according to claim 12,
wherein an element isolating region for electrically isolating the active element, the semiconductor resistive element, and an other element from each other is formed by said implanting.

14. The method for manufacturing a semiconductor device according to claim 12,
wherein in said implanting, the helium ions are implanted at a dose of 1×10¹² cm⁻² to 1×10¹⁴ cm⁻² inclusive.
